(19) United States
(12) Patent Application Publication
(10) Pub. No.: US 2004/0123528 A1
(43) Pub. Date: Jul. 1, 2004

(54) CMP slurry for semiconductor device, and method for manufacturing semiconductor device using the same

(76) Inventors: Jong Goo Jung, Gyeonggi-do (KR); Hyung Soon Park, Gyeonggi-do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/609,977

(22) Filed: Jun. 30, 2003

(30) Foreign Application Priority Data
Dec. 30, 2002 (KR) 2002-86668
Dec. 30, 2002 (KR) 2002-87193

(51) Int. Cl. C09C 1/68; H01L 21/76; B24D 3/02; H01L 21/302

(52) U.S. Cl. 51/309; 438/400; 438/424; 438/693

(57) ABSTRACT

A CMP slurry for a semiconductor device and a method for manufacturing the semiconductor device using the same, more specifically, a slurry including an additive having high affinity to a nitride film, and a method for polishing a complex film consisting of a polysilicon film and an oxide film or an oxide film using the same are described herein. When the complex film consisting of the polysilicon film and the oxide film removed by using the CMP slurry, a hard mask film which is the nitride film is not removed. Therefore, a polysilicon plug of the semiconductor device can be formed without exposing a word line electrode. In addition, when the oxide film is removed by using the CMP slurry, the slurry includes Al or SiO2 having spherical shaped particles as an abrasive, to form an STI type device isolation film which does not have scratches.

### BACKGROUND

### TECHNICAL FIELD

The present disclosure relates to a chemical mechanical polishing (CMP) slurry for a semiconductor device and a method for manufacturing the semiconductor device using the same, and more particularly to a method for forming a polysilicon plug by removing a complex film consisting of a polysilicon film and an oxide film, or forming an STI type device isolation film by removing an oxide film via a CMP process using a slurry including an additive having high affinity to a nitride film.

In general, a polysilicon plug has been used as a contact plug for manufacturing a high integration semiconductor device. The polysilicon plug is formed by depositing a polysilicon film on the whole surface of a semiconductor substrate on which a contact hole has been formed, and performing a CMP process on the polysilicon film.

FIG. 1a is a top plan view after formation of a word line, FIG. 1b is a top plan view after formation of a polysilicon plug contact, and FIGS. 2a through 2e are cross-sectional diagrams schematically illustrating conventional methods for forming a polysilicon plug of a semiconductor device.

Here, I represents a cell region and II represents a peripheral circuit region.

FIG. 2a illustrates a cross section wherein an interlayer insulating film is stacked on an A-A′ cross section of FIG. 1a.

Referring to FIG. 2a, stacked patterns of word lines 12 and hard mask films 14 are formed on a semiconductor substrate 10. Here, the hard mask films 14 are composed of nitride films with a thickness t1.

Thereafter, nitride films (not shown) are formed on the whole surface of the resulting structure, and spacers 16 are formed along the sidewalls of the stacked pattern of the word lines 12 and the hard mask films 14 by blanket etching the nitride film.

Then, a planarized interlayer insulating film 18 is formed on the whole surface of the resulting structure via CMP process. Here, the interlayer insulating film 18 is composed of an oxide film with a thickness t2 from the hard mask film 14.

FIG. 2b is a diagram illustrating a B-B′ cross section of FIG. 1b.

Referring to FIG. 2b, a polysilicon plug contact hole 20 is formed by etching the interlayer insulating film 18 by using a landing plug contact mask as an etching mask. Here, a region “C” shown in FIG. 1b represents an area wherein the polysilicon plug contact hole 20 is formed by etching the interlayer insulating film 18 while a region “D” represents an area wherein the polysilicon plug contact hole 20 is not formed.

When the polysilicon plug contact hole 20 is formed, the stacked patterns of the word lines 12 and the hard mask films 14 in the region “C” are exposed, and thus the top portions of the hard mask films 14 are partially removed. Accordingly, the thickness of the hard mask films 14 is reduced from t1 to t3. In addition, the interlayer insulating film 18 in the region “D” is partially removed by the CMP process. Therefore, when the polysilicon plug contact hole 20 has been formed, the thickness of the interlayer insulating film 18 is reduced from t2 to t4.

Referring to FIG. 2c, a polysilicon film 22 is deposited on the whole surface of the resulting structure. Here, the region “C” and the region “D” have a step difference of t5 due to a step difference resulted from the previous process. That is, the polysilicon film 22 has a step difference of t5 in the polysilicon plug contact hole 20, and of t6 from the hard mask film 14.

Referring to FIG. 2d, the polysilicon film 22 is etched so that the top portion of the polysilicon film 22 in the cell region (I) can be partially removed and the polysilicon film 22 in the peripheral circuit region (II) can be wholly removed.

Referring to FIG. 2e, the CMP process is performed on the polysilicon film 22 in the cell region (I) and the interlayer insulating film 18 in the peripheral circuit region (II) by using a slurry whose polishing speed of an oxide film is similar to that of a nitride film and using the hard mask film 14 in the cell region (I) as a polishing barrier film until the hard mask film 14 in the cell region (I) is exposed. The polishing process must be performed by a thickness of at least t6 to completely separate a polysilicon plug 24 into P1 region and P2 region.

Here, “Pinocchio” defects are not generated for using the slurry whose polishing speed of the oxide film is similar to that of the nitride film. However, the interlayer insulating film 18 in the peripheral circuit region (II) is easily removed, and the hard mask film 14 composed of the nitride film is easily removed, thereby exposing the word line 12.

FIG. 3 is an SEM photograph showing an exposed word line after formation of the polysilicon plug of the semiconductor device. As indicated by E, the word line is exposed due to loss of the hard mask film on the word line in the peripheral circuit region (II). As described above, when the word line is exposed, misalignment is generated in a subsequent process, and a bridge is formed between a word line wire and a storage node contact or leakage current increases, which result in failure of the device.

On the other hand, a conductive active region and a device isolation region for isolating devices are formed on a semiconductor substrate for a transistor or a capacitor.

A Local Oxidation of Silicon (LOCOS) process, which is a device isolation method has been suggested, wherein a device isolation region is formed by selectively growing a thick oxide film on a semiconductor substrate using a thermal oxidation method.

However, as semiconductor devices are required to have higher densities, reduction of the size of devices and insulation between devices became more difficult when the LOCOS process is used. In order to improve integration density and insulation properties of devices, a Shallow Trench Isolation (STI) process has been suggested.

In the STI process, a trench having a predetermined depth is formed on a semiconductor substrate and then filled with an oxide film which is an insulating material. The unnecessary portion of the oxide film is then etched by the CMP process to form a device isolation region on the semiconductor substrate.

FIGS. 4a through 4g are cross-sectional diagrams schematically illustrating conventional methods for forming an STI type device isolation film of a semiconductor device.

Referring to FIG. 4a, a pad oxide film 13 and a pad nitride film 15 are sequentially formed on a semiconductor substrate 11.

Referring to FIG. 4b, a trench is formed on a presumed device isolation region of the semiconductor substrate 11 by etching the pad nitride film 15, the pad oxide film 13 and a predetermined thickness of semiconductor substrate 11 via a photoetching process using a device isolation mask (not shown). Here, the pad nitride film 15 has a thickness t7 after etching the trench.

Referring to FIG. 4c, sidewall oxide films 17 are formed on the inner walls of the trench, namely the bottom and sidewalls of the semiconductor substrate 11 and the sidewalls of the pad oxide film 13 which have been etched and exposed due to the trench forming process.

The sidewall oxide film 17 serves to remove defects which may be generated during the trench forming process, and reduce interface trap charges generated between the bottom and sidewalls of the trench and a filling oxide film formed in a subsequent process.

Referring to FIG. 4d, a filling oxide film 19 is formed on the whole surface of the resulting structure. Here, a thickness t8 of the filling oxide film 19 in a cell region is smaller than a thickness t9 of the filling oxide film 19 in a peripheral circuit region due to properties of the process.

Referring to FIG. 4e, a CMP process is performed on the filling oxide film 19 by using the pad nitride film 15 as a polishing barrier film until the pad nitride film 15 is exposed. Here, a thickness t10 of the pad nitride film 15 after the CMP process is smaller than the thickness t7 of the pad nitride film 15 after the trench etching process.

A slurry having a high polishing selectivity to an oxide film must be used to efficiently planarize the filling oxide film 19 having a step difference. Accordingly, a slurry including CeO2 (refer to FIG. 5) as an abrasvie is used to improve the polishing selectivity to the oxide film, instead of a general CMP slurry for an oxide film including SiO2 or Al2O3 as an abrasive.

However, a lot of scratches 21 are formed in the polished region because the particles of CeO2 are large and rough.

Referring to FIG. 4f, the scratches 21 formed deep into the semiconductor substrate 11 are not removed even by removing the pad nitride film 15 from the resulting structure.

FIG. 4g is an SEM photograph showing the result of FIG. 4f, after performing the CMP process on the filling oxide film 19 by using the slurry having the high polishing selectivity to the oxide film and then removing the pad nitride film 15 from the resulting structure. As shown in the photograph of FIG. 4g, a lot of scratches are formed over a wide region.

As described above, the conventional process generates many scratches by performing the CMP process using the slurry including CeO2 which have large particles and rough surfaces in order to improve the polishing selectivity to the oxide film. Such scratches cause failure of the device, and thus reduce a yield of the device.

### SUMMARY OF THE DISCLOSURE

A CMP slurry composition including an additive having high affinity to a nitride film is disclosed herein to improve a yield of a semiconductor device by preventing failure due to exposure of the word line when the polysilicon plug is formed via a CMP process, and to prevent scratches on the semiconductor substrate when an STI type device isolation film is formed.

A method for forming a polysilicon plug of a semiconductor device using the CMP slurry composition, and a method for forming an STI type device isolation film of the semiconductor device are also disclosed herein.

### BRIEF DESCRIPTION OF THE DRAWINGS

The slurries and methods will be described in terms of several embodiments and references will be made to the attached drawings, wherein:

FIG. 1a is a top plan view after formation of a word line;

FIG. 1b is a top plan view after formation of a polysilicon plug contact;

FIGS. 2a through 2e are cross-sectional diagrams schematically illustrating conventional methods for forming a polysilicon plug of a semiconductor device;

FIG. 3 is an SEM photograph showing an exposed word line after formation of the polysilicon plug of the semiconductor device;

FIGS. 4a through 4f are cross-sectional diagrams schematically illustrating conventional methods for forming an STI type device isolation film of a semiconductor device;

FIG. 4g is an SEM photograph showing the result of FIG. 4f;

FIG. 5 is an SEM photograph showing a shape of a general slurry;

FIGS. 6a through 6f are cross-sectional diagrams schematically illustrating methods for forming a polysilicon plug of a semiconductor device in accordance with this disclosure;

FIGS. 7a through 7g are cross-sectional diagrams schematically illustrating methods for forming an STI type device isolation film of a semiconductor device in accordance with this disclosure; and

FIG. 8 is an SEM photograph showing a disclosed slurry.

### DETAILED DESCRIPTION OF THE PRESENTLY

### PREFERRED EMBODIMENTS

The CMP slurry composition of the present invention includes an anion compound, an abrasive and water.

The anion compound includes RC02M, ROSO3M, RS03M, RP04M2 or R3N, wherein R is a linear or branched substituted or unsubstituted C10-C50 aliphatic hydrocarbon group, or linear or branched substituted or unsubstituted C10-C50 aromatic hydrocarbon group; M is a hydrogen ion, an alkaline metal ion such as Na+ or K+, an alkaline earth metal ion such as Mg2+ or Ca2+, or NH4+; and R of R3N is identical or different. The linear or branched substituted aliphatic and aromatic hydrocarbon groups include at least one of ethylene oxide group, carbon-carbon double bond and carbon-carbon triple bond, respectively.

Examples of the anion compound are selected from the group consisting of lauric acid, oleic acid, stearic acid, sodium stearate, sodium lauric sulfate, sodium lauryl ether sulfate, ammonium lauryl sulfate, triethanol ammonium lauryl sulfate, sodium octyl sulfate, dodecyl benzene sulfonic acid, sodium dodecyl benzene sulfonate, mono lauryl phosphate, lauryl ether phosphate and dimethyl laurylamine.

The CMP slurry composition is used to polish a complex film consisting of a polysilicon film and an oxide film, or an oxide film.

When the CMP slurry composition is used to polish the complex film consisting of the polysilicon film and the oxide film, 0.01 to 10 wt %, preferably 0.1 to 5 wt % of anion compound is used in the total weight of slurry, the abrasive is selected from the group consisting of colloidal SiO2, fumed SiO2, Al2O3, CeO2 and combinations thereof, a size of the abrasive ranges from 20 to 300 nm, 0.5 to 40 wt % of abrasive is used in the total weight of slurry, and pH of the slurry ranges from 2 to 7, more preferably 3 to 6.

When the CMP slurry composition is used to polish the oxide film, 0.01 to 2 wt %, preferably 0.1 to 1.5 wt % of anion compound is used in the total weight of slurry, the abrasive is selected from the group consisting of SiO2, Al2O3 and combinations thereof, a size of the abrasive ranges from 20 to 300 nm, 0.5 to 40 wt % of abrasive is used in the total weight of slurry, and pH of the slurry ranges from 2 to 9, more preferably 3 to 7.

In addition, the method for forming the polysilicon plug of the semiconductor device includes the steps of: (a) forming a stacked pattern of a word line and a hard mask film on a semiconductor substrate; (b) forming a spacer on the sidewalls of the stacked pattern; (c) forming an interlayer insulating film on the whole surface of the resulting structure; (d) forming a polysilicon plug contact hole by defining a polysilicon plug contact hole region and selectively etching the interlayer insulating film to expose the stacked pattern present in the contact hole region; (e) depositing a polysilicon film on the whole surface of the resulting structure; and (f) performing a CMP process on the whole surface of the resulting structure by using the CMP slurry of the present invention until the hard mask film is exposed.

The method for forming the STI type device isolation film of the semiconductor device includes the steps of: (a) sequentially forming a pad oxide film and a pad nitride film on a semiconductor substrate; (b) forming a trench on a presumed device isolation region of the semiconductor substrate, by etching the pad nitride film, the pad oxide film and a predetermined thickness of semiconductor substrate via a photoetching process using a device isolation mask; (c) forming a sidewall oxide film on the surface of the semiconductor substrate which has been exposed during the trench forming process and the sidewalls of the pad oxide film; (d) forming a filling oxide film on the whole surface of the resulting structure; (e) performing a CMP process on the filling oxide film by using the pad nitride film as a polishing barrier film and using the CMP slurry of the present invention until the pad nitride film is exposed; and (f) removing the pad nitride film from the resulting structure.

On the other hand, the principle of the present invention will be explained.

The CMP slurry uses the anion compound having high affinity to the nitride film as an additive. The anion compound includes an alkyl group substituent, has negative charges and interacts with the surface of the nitride film having positive charges.

That is, the polysilicon film in the cell region and the interlayer insulating film in the peripheral circuit region are removed via the CMP process using the present CMP slurry for the complex film in order to form the polysilicon plug. Here, when the hard mask film which is the polishing barrier film is exposed, cation-anion interaction occurs between the anion compound and the surface of the hard mask film.

As a result, the surface of the hard mask film has a small contact area with the abrasive, and thus shows a low polishing speed. Conversely, the surfaces of the polysilicon film and the interlayer insulating film have negative charges, and thus do not interact with the anion compound. Accordingly, the surfaces of the polysilicon film and the interlayer insulating film have a large contact area with the abrasive, and thus show a high polishing speed.

In addition, the filling oxide film is removed via the CMP process using the present CMP slurry for the oxide film in order to form the STI device isolation film. Here, when the nitride film which is the polishing barrier film is exposed, cation-anion interaction occurs between the anion compound and the surface of the nitride film.

As a result, the surface of the nitride film has a small contact area with the abrasive, and thus shows a low polishing rate. Conversely, the surface of the oxide film has negative charges, and thus does not interact with the additive. Accordingly, the surface of the oxide film has a large contact area with the abrasive, and thus shows a high polishing ratio. Moreover, the present CMP slurry for the oxide film uses an abrasive having spherical shaped particles such as SiO2 and Al2O3, and thus does not form scratches during the polishing process.

Many changes and modifications to the embodiments described herein could be made. The scope of some changes is discussed above. The scope of others will become apparent from the appended claims.

A method for forming a polysilicon plug of a semiconductor device by using a CMP slurry will be explained.

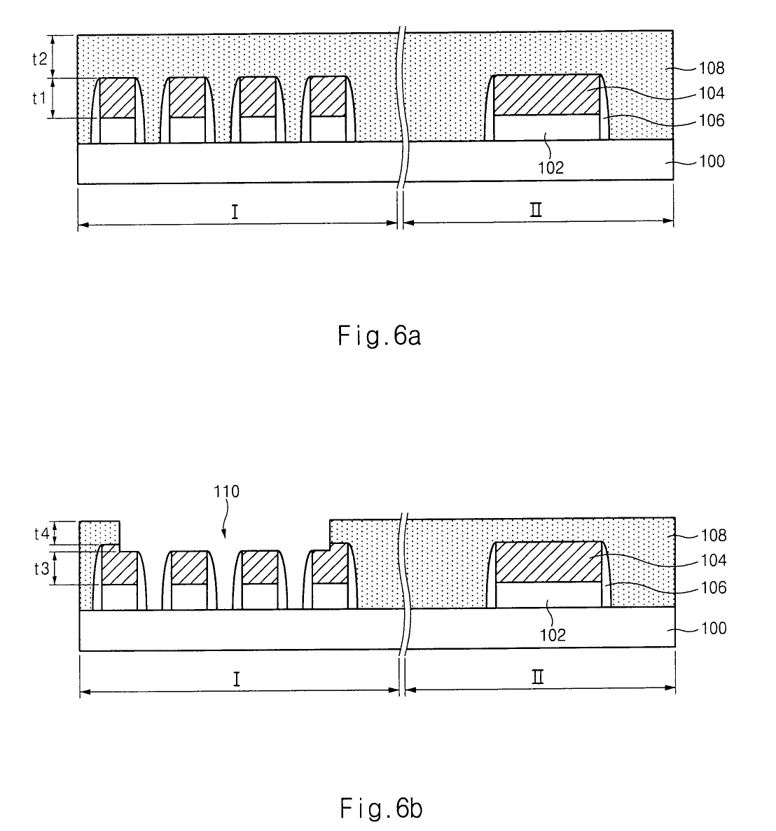

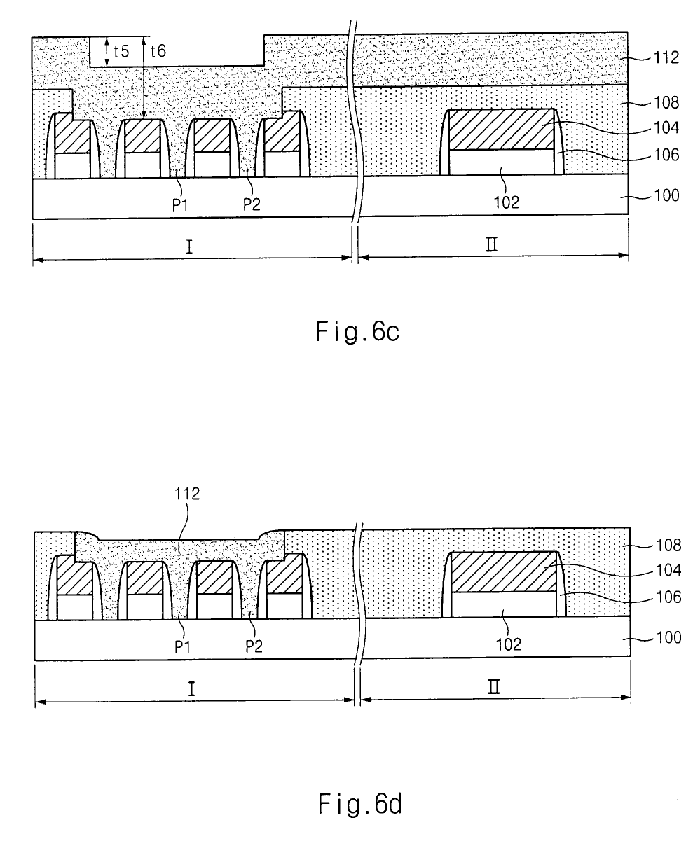

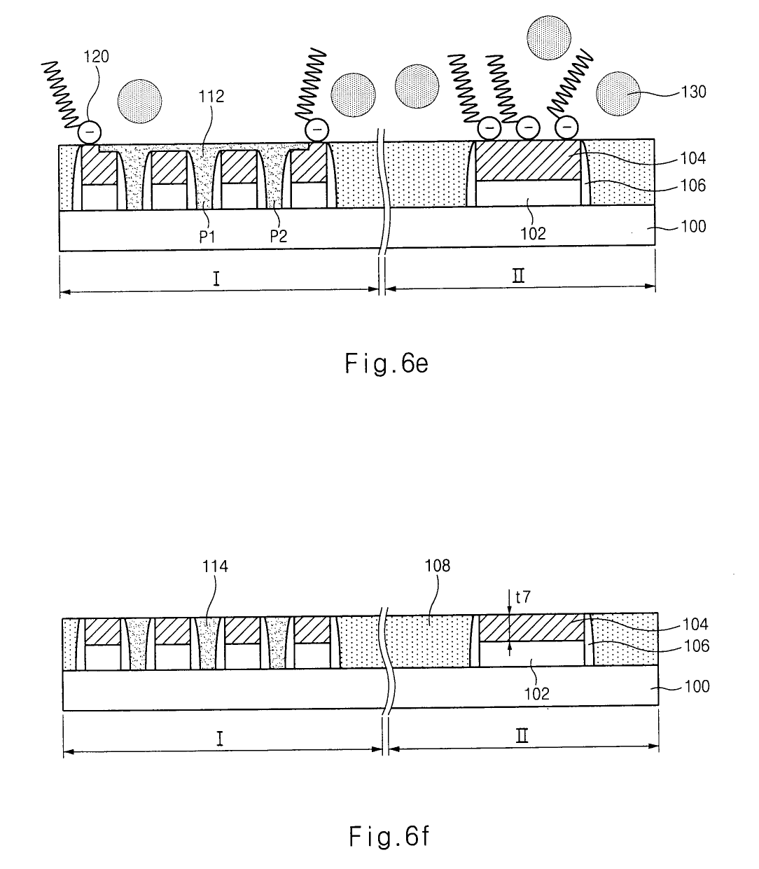

FIGS. 6a through 6f are cross-sectional diagrams schematically illustrating methods for forming the polysilicon plug of a semiconductor device.

Here, I represents a cell region and II represents a peripheral circuit region.

Referring to FIG. 6a, stacked patterns of word lines 102 and hard mask films 104 are formed on a semiconductor substrate 100 and a interlayer insulating film 108 is stacked thereon.

Here, the hard mask films 104 are composed of nitride films with a thickness t1.

The word line 102 is composed of a polysilicon film, doped polysilicon film, WSix film, WN film, W film, TiSix film, or combinations thereof, and a word line 102 pattern is formed via a plasma etching process using C12 or CC14 gas as a source to obtain a high selectivity to a gate oxide film formed in a subsequent process.

Thereafter, nitride films (not shown) are formed on the whole surface of the resulting structure, and spacers 106 are formed along the sidewalls of the stacked patterns of the word lines 102 and the hard mask films 104 by blanket etching the nitride film.

Then, a planarized interlayer insulating film 108 is formed on the whole surface of the resulting structure via CMP process. Here, the interlayer insulating film 108 is composed of a BPSG(borophospho silicate glass) oxide film, PSG(phospho silicate glass) oxide film, FSG(fluoro silicate glass) oxide film, PE-TEOS(plasma enhanced-tetraethyl ortho silicate) oxide film, PE-SiH4 oxide film, HDP USG(high density plasma undoped silicon glass) oxide film, APL(advanced planarization layer) oxide film, or combinations thereof with a thickness t2 from the hard mask film 104.

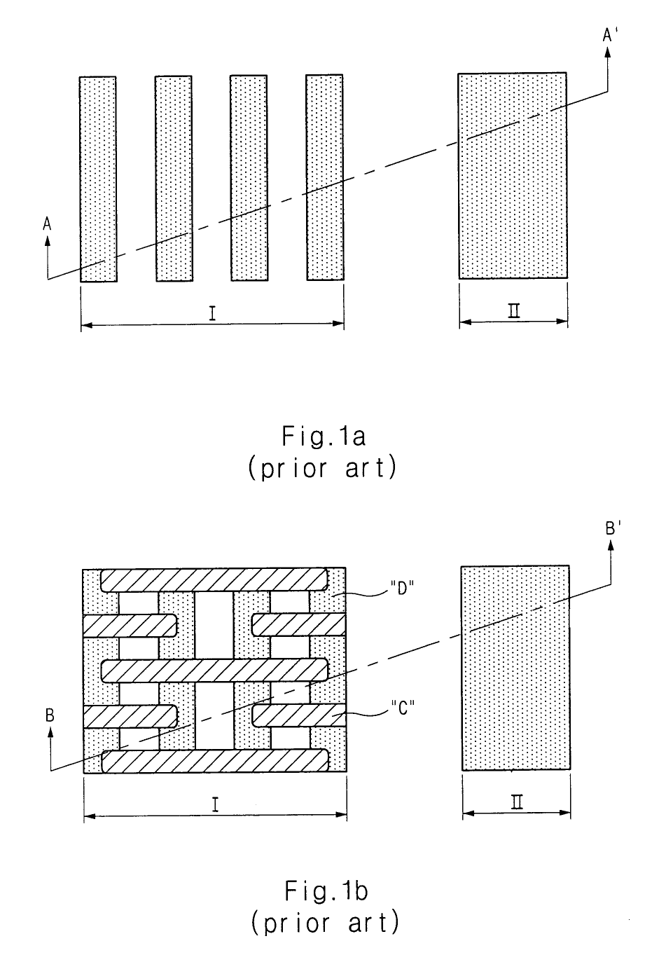

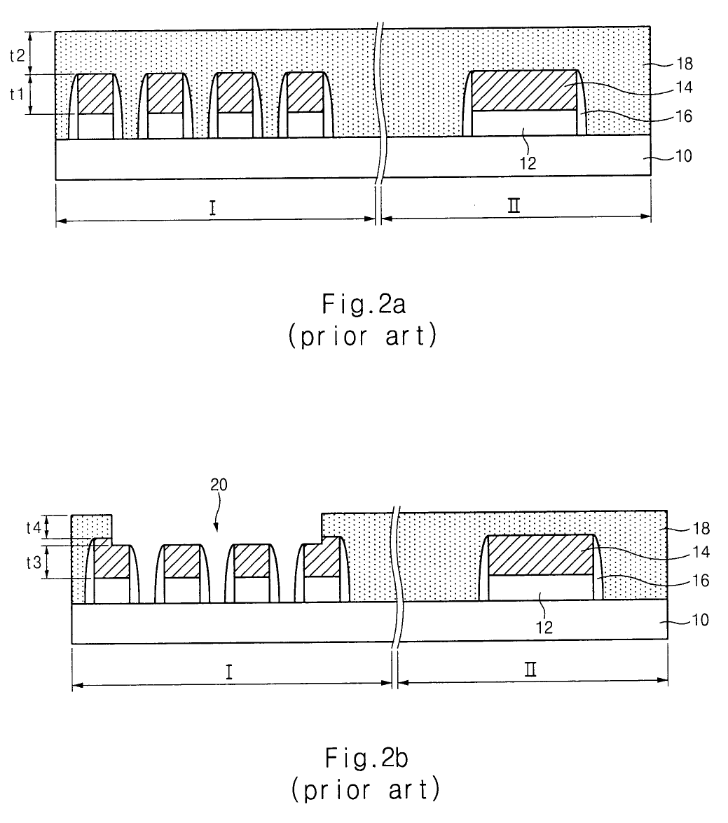

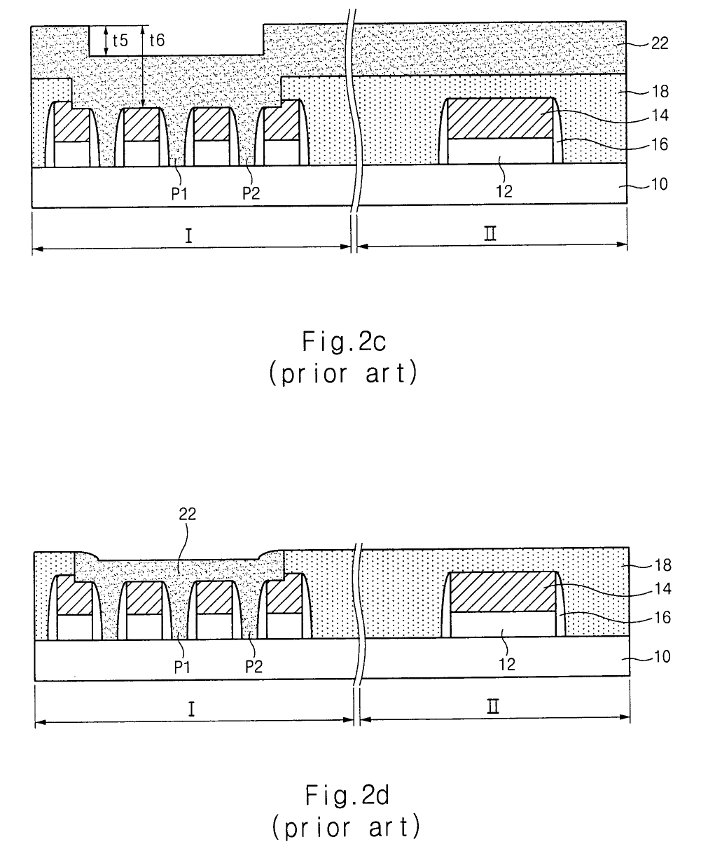

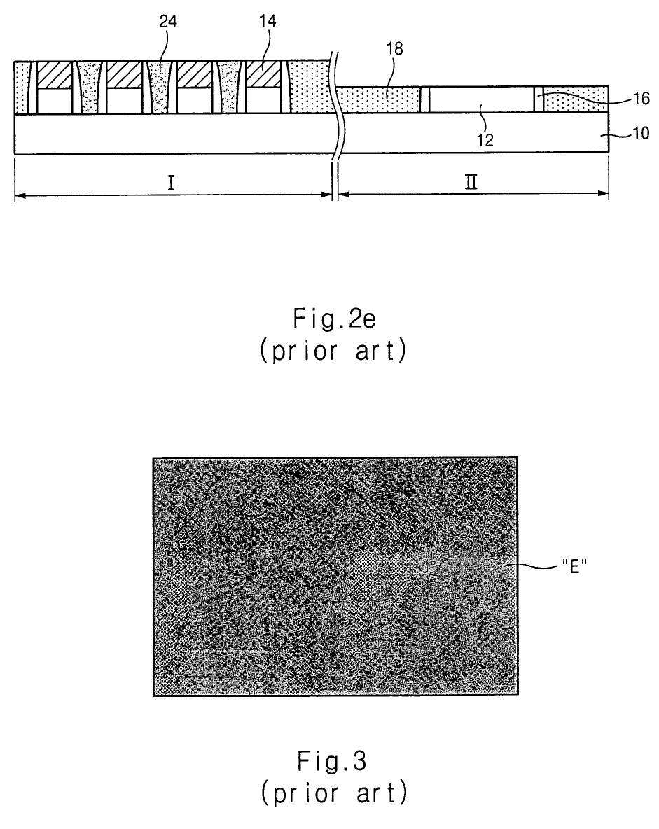

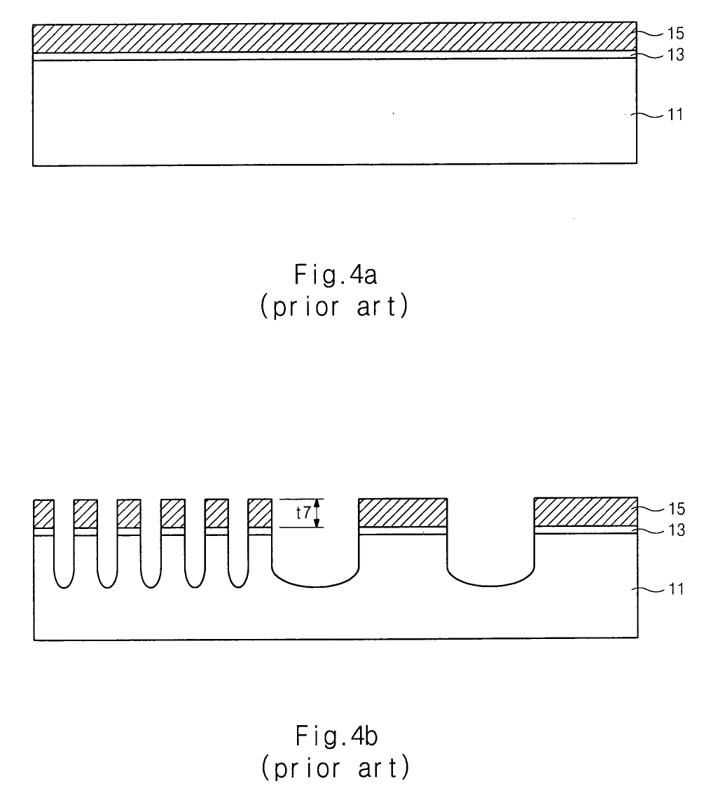

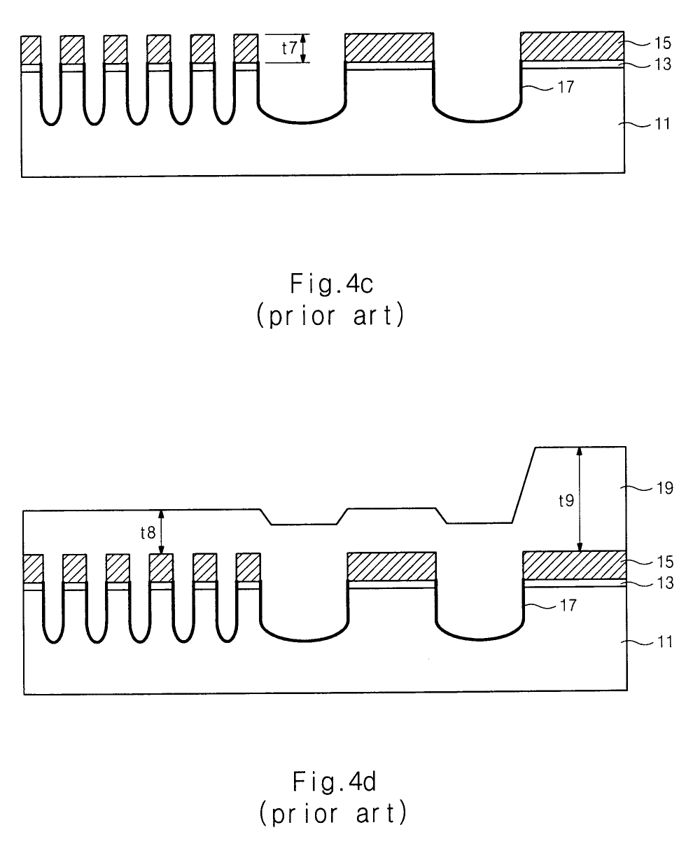

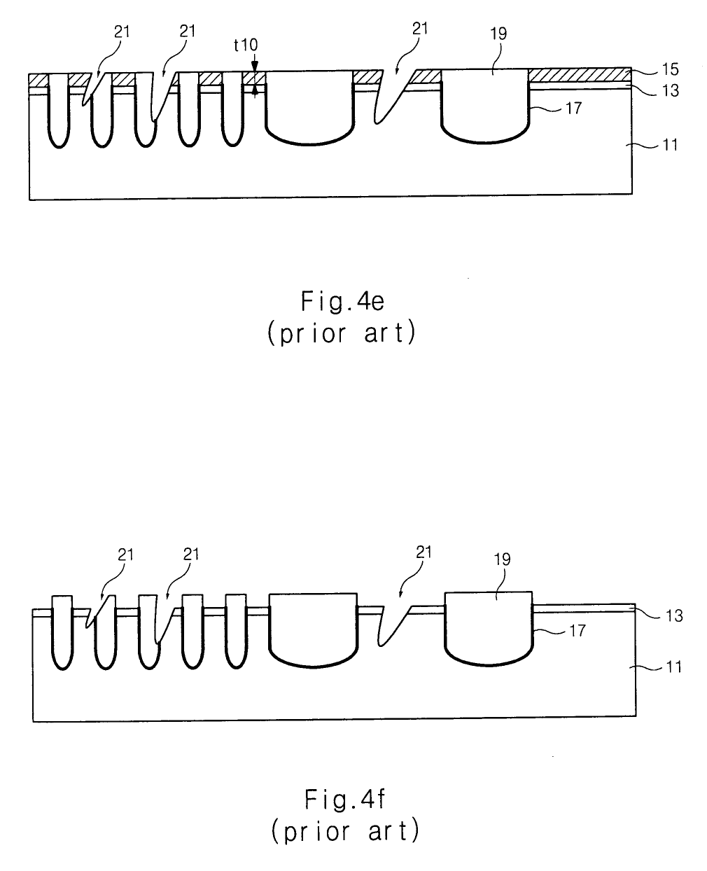

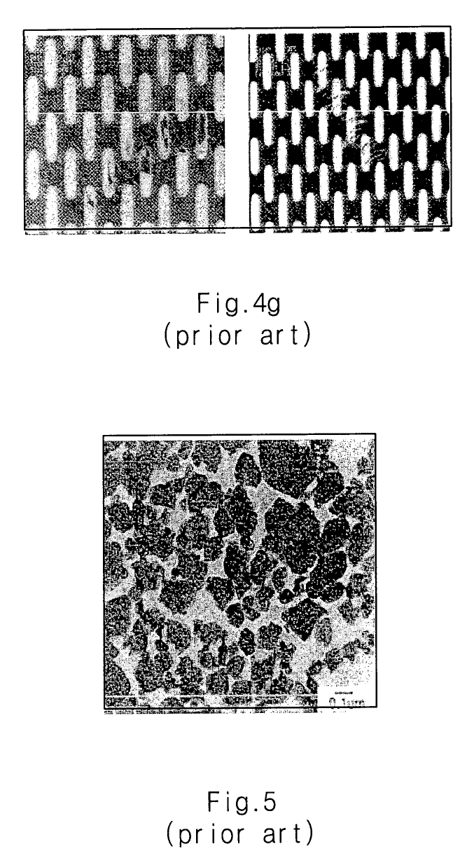

FIG. 6b is a diagram illustrating a B-B′ cross section of FIG. 1b.

Referring to FIG. 6b, a polysilicon plug contact hole 110 is formed by defining a polysilicon plug contact hole region and selectively etching the interlayer insulating film 108 to expose the stacked pattern present in the contact hole region.

That is, the polysilicon plug contact hole 110 is formed by removing the interlayer insulating film 108 between the stacked patterns via a self-alignment contact process using a landing plug contact mask as an etching mask, and using C4F8 as a source to improve a selectivity to an oxide film.

Here, a region “C” shown in FIG. 1b represents an area wherein the polysilicon plug contact hole 110 is formed by etching the interlayer insulating film 108 while a region “D” represents an area wherein the polysilicon plug contact hole 110 is not formed.

When the polysilicon plug contact hole 110 is formed, the stacked patterns of the word lines 102 and the hard mask films 104 in the region “C” are exposed, and thus the top portions of the hard mask film 104 are partially removed. Accordingly, the thickness of the hard mask films 104 is reduced from t1 to t3. In addition, the interlayer insulating film 108 in the region “D” is partially removed by the CMP process. Therefore, when the polysilicon plug contact hole 110 has been formed, the thickness of the interlayer insulating film 108 is reduced from t2 to t4.

Referring to FIG. 6c, a polysilicon film 112 is deposited on the whole surface of the resulting structure. Here, the region “C” and the region “D” have a step difference of t5 due to a step difference resulted from the previous process. That is, the polysilicon film 112 has a step difference of t5 in the polysilicon plug contact hole 110, and of t6 from the hard mask film 104.

Preferably, the polysilicon film 112 is a doped polysilicon film formed via an in-situ doping process using SiH4 or Si2H6 as a source.

Referring to FIG. 6d, the polysilicon film 112 is etched so that the top portion of the polysilicon film 112 in the cell region (I) can be partially removed and the polysilicon film 112 in the peripheral circuit region (II) can be wholly removed.

Referring to FIG. 6e, the CMP process is performed on the polysilicon film 112 in the cell region (I) and the interlayer insulating film 108 in the peripheral circuit region (II) by using the CMP slurry and the hard mask film 104 in the cell region (I) as a polishing barrier film until the hard mask film 104 in the cell region (I) is exposed. The polishing process must be performed by a thickness of at least t6 to completely separate a polysilicon plug 114 into P1 region and P2 region.

Preferably, the CMP process is performed by using a hard pad under the conditions of a polishing pressure of 2 to 6 psi, a table revolution number of 10 to 200 rpm in a rotary type equipment, a table revolution number of 100 to 700 rpm in an orbital type equipment, and a table movement speed of 100 to 700 fpm in a linear equipment.

As a result of the CMP process, a polishing selectivity of the hard mask film 104 to the polysilicon film 112 to the interlayer insulating film 108 is in the range of 1:2˜10:2˜10. The surface of the hard mask film 104 has a small contact area with an abrasive 130, and thus shows a low polishing speed. Conversely, the surfaces of the polysilicon film 112 and the interlayer insulating film 108 have negative charges, and thus do not interact with an additive 120. Accordingly, the surfaces of the polysilicon film 112 and the interlayer insulating film 108 have a large contact area with the abrasive 130, and thus show a high polishing speed.

The CMP slurry composition includes an anion compound which is the additive having high affinity to the nitride film, an abrasive and water. The anion compound is RCO2M, ROSO3M, RS03M, RPO4M2, R3N or combinations thereof.

Here, R is a linear or branched substituted or unsubstituted C 10-C50 aliphatic hydrocarbon group, or linear or branched substituted or unsubstituted C10—C50 aromatic hydrocarbon group; M is a hydrogen ion, an alkaline metal ion such as Na+ or K+, an alkaline earth metal ion such as Mg2+ or Ca2+, or NH4+; and R of R3N is identical or different.

Preferably, the linear or branched substituted aliphatic and aromatic hydrocarbon groups include at least one of ethylene oxide group, carbon-carbon double bond and carbon-carbon triple bond, respectively.

Exemplary anion compounds include lauric acid, oleic acid, stearic acid, sodium stearate, sodium lauric sulfate, sodium lauryl ether sulfate, ammonium lauryl sulfate, triethanol ammonium lauryl sulfate, sodium octyl sulfate, dodecyl benzene sulfonic acid, sodium dodecyl benzene sulfonate, mono lauryl phosphate, lauryl ether phosphate or dimethyl laurylamine.

Preferably, sodium stearate, sodium lauric sulfate, sodium dodecyl benzene sulfonate or lauryl ether phosphate is used.

In addition, 0.01 to 10 wt %, preferably 0.1 to 5 wt % of anion compound is used in the total weight of slurry. When the anion compound is used over 10 wt %, because the polysilicon film, the oxide film and the nitride film are concentrated in the cell region having high pattern density, a lot of anion compounds interact with the nitride film, to reduce a polishing speed on the polysilicon film and the oxide film adjacent to the nitride film. On the other hand, when the anion compound is used below 0.01 wt %, properties of the slurry are deteriorated.

The abrasive is colloidal SiO2, fumed SiO2, Al2O3, CeO2 or combinations thereof. A size of the abrasive ranges from 20 to 300 nm, and 0.5 to 40 wt % of abrasive is used in the total weight of slurry. In more detail, 5 to 20 wt % of SiO2 is used in the total weight of slurry, 5 to 15 wt % of Al2O3 is used in the total weight of slurry, and 0.5 to 5 wt % of CeO2 is used in the total weight of slurry.

Preferably, pH of the slurry ranges from 2 to 7, more preferably 3 to 6. A buffer solution including H3PO4, H2CO3 or CH3COOH and salts thereof are added to maintain the pH range.

FIG. 6f shows a result of the CMP process using the CMP slurry, namely the polysilicon plug 114 completely separated into P1 region and P2 region. Here, a thickness of the hard mask film 104 is t7, and the word line 102 is not exposed because the hard mask film 104 in the peripheral circuit region (II) is not removed.

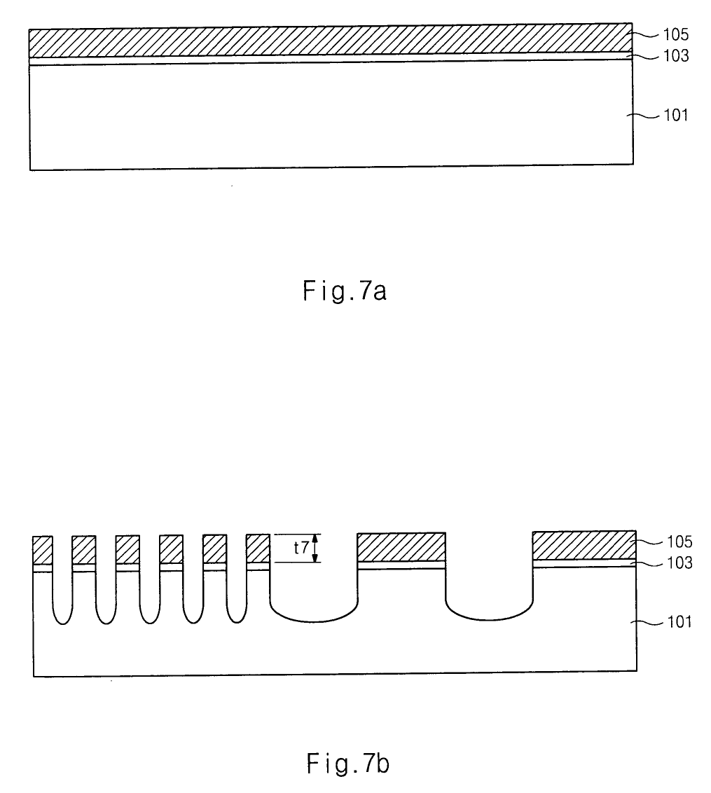

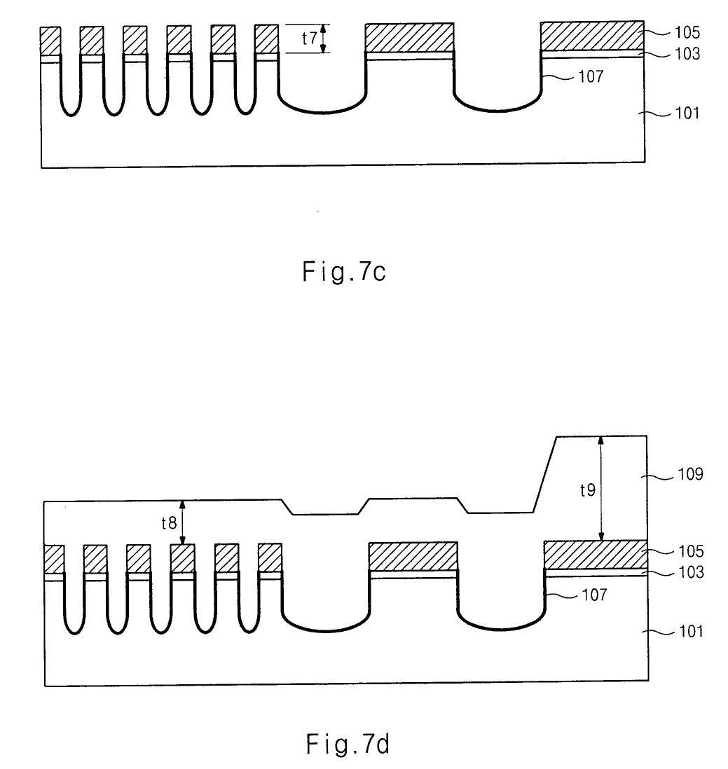

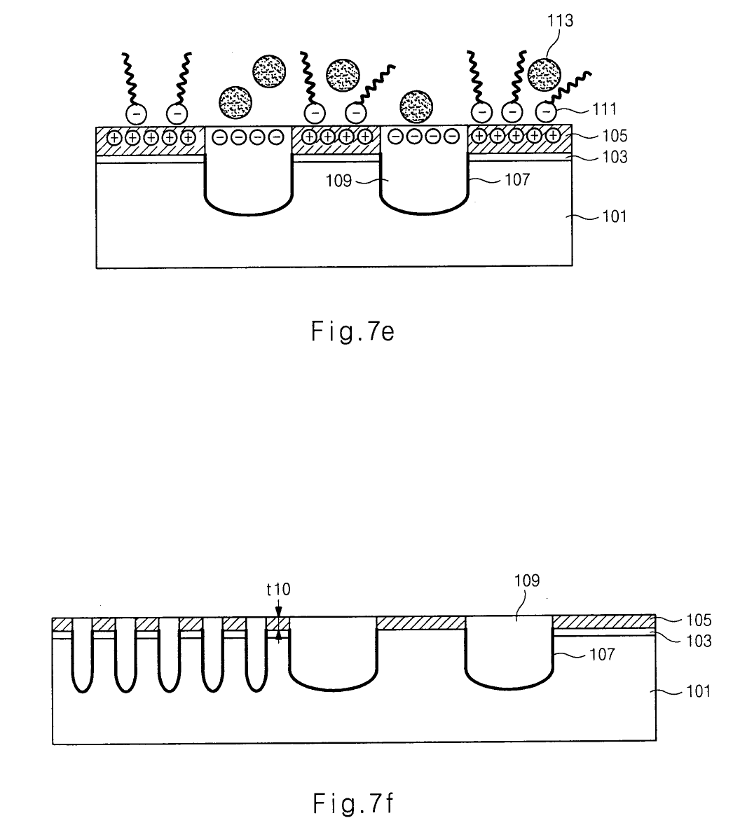

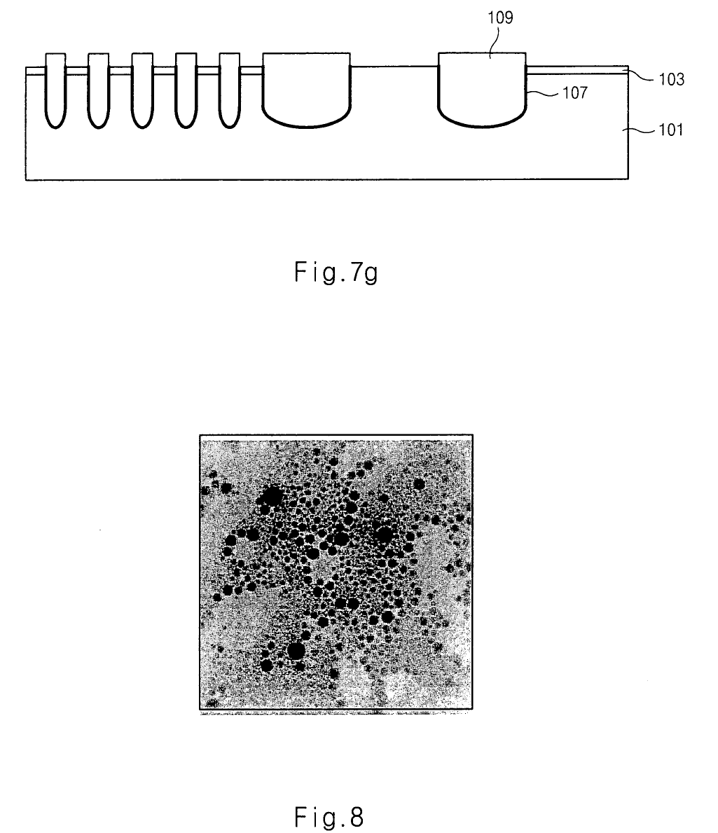

A method for forming an STI type device isolation film of a semiconductor device using a CMP slurry will be described in reference to FIGS. 7a-7g.

FIGS. 7a through 7g are cross-sectional diagrams schematically illustrating methods for forming an STI type device isolation film of the semiconductor device.

Referring to FIG. 7a, a pad oxide film 103 and a pad nitride film 105 are sequentially formed on a semiconductor substrate 101.

The pad oxide film 103 is formed at a thickness of 10 to 200 Å via a dry oxidation process using O2 source or a wet oxidation process using H2O source, and the pad nitride film 105 is formed at a thickness of 200 to 2000 Å via an LPCVD process using SiH2C12 and NH3 as a source, or a PECVD process using SiH4 and NH3 as a source.

Referring to FIG. 7b, a trench is formed at a depth of 1500 to 3000 Å on a presumed device isolation region of the semiconductor substrate 101, by etching the pad nitride film 105, the pad oxide film 103 and a predetermined thickness of semiconductor substrate 101 via a photoetching process using a device isolation mask (not shown). Here, a thickness of the pad nitride film 105 is t7 after etching the trench.

Referring to FIG. 7c, sidewall oxide films 107 are formed on the inner walls of the trench, more specifically on the bottom and sidewalls of the semiconductor substrate 101 and the sidewalls of the pad oxide film 103 which have been etched and exposed during the trench forming process.

The sidewall oxide film 107 serves to remove defects which may be generated during the trench forming process, and reduce interface trap charges generated between the bottom and sidewalls of the trench and a filling oxide film formed in a subsequent process.

The sidewall oxide film 107 is formed at a thickness of 50 to 200 Å under a temperature over 1000° C. and an oxygen atmosphere in a furnace.

Referring to FIG. 7d, a filling oxide film 109 is formed on the whole surface of the resulting structure. Here, a thickness t8 of the filling oxide film 109 in a cell region is smaller than a thickness t9 of the filling oxide film 109 in a peripheral circuit region due to properties of the process.

The filling oxide film 109 is composed of an HDP(high density plasma) oxide film, PE-TEOS(plasma enhanced-tetraethyl ortho silicate) oxide film, O3-TEOS(O3-tetraethyl ortho silicate) oxide film, APL(advanced planarization layer) oxide film, BPSG(borophospho silicate glass) oxide film, PSG(phospho silicate glass) oxide film, or combinations thereof. The filling oxide film 109 has a thickness of 3000 to 8000 Å from the pad nitride film 104.

Referring to FIG. 7e, a CMP process is performed on the filling oxide film 109 by using the pad nitride film 105 as a polishing barrier film until the pad nitride film 105 is exposed.

Preferably, the CMP process is performed by using a hard pad under the conditions of a polishing pressure of 2 to 6 psi, a table revolution number of 10 to 200 rpm in a rotary type equipment, a table revolution number of 100 to 700 rpm in an orbital type equipment, and a table movement speed of 100 to 700 fpm in a linear equipment.

As a result of the CMP process, the surface of the pad nitride film 105 has a small contact area with an abrasive 113, and thus shows a low polishing speed. Conversely, the surface of the filling oxide film 109 has negative charges, and thus does not interact with an additive 111. Accordingly, the surface of the filling oxide film 109 has a large contact area with the abrasive 113, and thus shows a high polishing speed. Moreover, the slurry uses the abrasive having spherical shaped particles such as SiO2 and Al2O3, and thus does not form scratches during the polishing process.

The CMP slurry composition includes an anion compound which is the additive having high affinity to the nitride film, an abrasive having spherical shaped particles such as SiO2 and Al2O3, and water. The anion compound is RC02M, ROSO3M, RS03M, RP04M2, R3N or combinations thereof.

Here, R is a linear or branched substituted or unsubstituted C10-C50 aliphatic hydrocarbon group, or linear or branched substituted or unsubstituted C10-C50 aromatic hydrocarbon group; M is a hydrogen ion, an alkaline metal ion such as Na+ or K+, an alkaline earth metal ion such as Mg2+ or Ca2+, or NH4+; and R of R3N is identical or different.

Preferably, the linear or branched substituted aliphatic and aromatic hydrocarbon groups include at least one of ethylene oxide group, carbon-carbon double bond and carbon-carbon triple bond, respectively.

Exemplary anion compounds include lauric acid, oleic acid, stearic acid, sodium stearate, sodium lauric sulfate, sodium lauryl ether sulfate, ammonium lauryl sulfate, triethanol ammonium lauryl sulfate, sodium octyl sulfate, dodecyl benzene sulfonic acid, sodium dodecyl benzene sulfonate, mono lauryl phosphate, lauryl ether phosphate or dimethyl laurylamine.

In addition, 0.01 to 2 wt %, preferably 0.1 to 1.5 wt % of anion compound is used in the total weight of slurry. When the anion compound is used over 2 wt %, because the oxide film and the nitride film are concentrated in the cell region having high pattern density, a lot of anion compounds interact with the nitride film, to reduce a polishing speed in the oxide film adjacent to the nitride film. On the other hand, when the anion compound is used below 0.01 wt %, properties of the slurry are deteriorated.

Preferably, a size of the abrasive ranges from 20 to 300 nm, and 0.5 to 40 wt % of abrasive is used in the total weight of slurry. In more detail, 5 to 20 wt % of SiO2 is used in the total weight of slurry, and 5 to 15 wt % of Al2O3 is used in the total weight of slurry.

Preferably, pH of the slurry ranges from 2 to 9, more preferably 3 to 7. A buffer solution including H3PO4, H2CO3 or CH3COOH and salts thereof is added to maintain the pH range.

Referring to FIG. 7f, the CMP process is performed on the filling oxide film 109 by using the pad nitride film 105 as a polishing barrier film until the pad nitride film 105 is exposed. The STI type device isolation film is formed without scratches. Here, a thickness t10 of the pad nitride film 105 after the CMP process is smaller than the thickness t7 of the pad nitride film 105 after the trench etching process.

Referring to FIG. 7g, the pad nitride film 105 is removed from the resulting structure by using H3PO4 as a main constituent.

The disclosed slurries and methods will be better understood by referring to the following examples, which are not intended to be limiting.

I. Preparation of Slurry of Invention

### EXAMPLE 1

To 40 wt % of slurry for an oxide film (Cabot, SS-25) including fumed SiO2 having a size of 20 to 300 nm were added 55 wt % of deionized water and 5 wt % of sodium stearate with stirring. And the resulting mixture was further stirred for about 30 minutes to be completely mixed and stabilized, to prepare a slurry of pH 6. Here, the content of the fumed SiO2 was 10 wt % based on the total weight of the prepared slurry.

### EXAMPLE 2

To 60 wt % of slurry for an oxide film (Bayer, LEVASIL 50CK/30% V1) including colloidal SiO2 having a size of 20 to 300 nm were added 1 wt % of sodium lauric sulfate with stirring and 39 wt % of deionized water. And the resulting mixture was further stirred for about 30 minutes to be completely mixed and stabilized, to prepare a slurry of pH 3. Here, the content of the colloidal SiO2 was 18 wt % based on the total weight of the prepared slurry.

### EXAMPLE 3

To 80 wt % of slurry for an oxide film including Al2O3 having a size of 20 to 300 nm were added 10 wt % of dodecyl benzene sulfonate with stirring and 10 wt % of deionized water. And the resulting mixture was further stirred for about 30 minutes to be completely mixed and stabilized, to prepare a slurry of pH 5. Here, the content of the Al2O3 was 10 wt % based on the total weight of the prepared slurry.

### EXAMPLE 4

To 20 wt % of slurry for an oxide film (Showa-Denko, GPL-C S2125)including CeO2 having a size of 20 to 300 nm were added 70 wt % of deionized water, 5 wt % of lauryl ether phosphate with stirring and 5 wt % of deionized water. And the resulting mixture was further stirred for about 30 minutes to be completely mixed and stabilized, to prepare a slurry of pH 6. Here, the content of the CeO2 was 1 wt % based on the total weight of the prepared slurry.

### EXAMPLE 5

To 90 wt % of slurry for an oxide film (Bayer, LEVASIL 50CK/30% V1) including SiO2 having a size of 50 to 300 nm were added 1 wt % of sodium lauric sulfate with stirring and 9 wt % of deionized water. And the resulting mixture was further stirred for about 30 minutes to be completely mixed and stabilized, to prepare a slurry of pH 7 (refer to FIG. 8). Here, the content of the SiO2 was 15 wt % based on the total weight of the prepared slurry.

### EXAMPLE 6

To 80 wt % of slurry for an oxide film including Al2O3 having a size of 50 to 300 nm were added 10 wt % of dodecyl benzene sulfonate with stirring and 10 wt % of deionized water. And the resulting mixture was further stirred for about 30 minutes to be completely mixed and stabilized, to prepare a slurry of pH 7. Here, the content of the Al₂O₃ was 10 wt % based on the total weight of the prepared slurry.

II. Manufacturing Semiconductor Device by using Slurry of Invention

### EXAMPLE 7

A CMP process was performed on the resulting structure of FIG. 6d under a polishing pressure of 3 psi and a table revolution number of 80 rpm (Rotary Type CMP equipment) by using a hard pad and the slurry of Example 1, to manufacture a semiconductor device including separated polysilicon plugs which do not have step differences and defects.

### EXAMPLE 8

A CMP process was performed on the resulting structure of FIG. 6d under a polishing pressure of 3 psi and a table revolution number of 600 rpm (Orbital Type CMP equipment) by using a hard pad and the slurry of Example 2, to manufacture a semiconductor device including separated polysilicon plugs which do not have step differences and defects.

### EXAMPLE 9

A CMP process was performed on the resulting structure of FIG. 6d under a polishing pressure of 4 psi and a table movement speed of 600 fpm (Linear Type CMP equipment) by using a hard pad and the slurry of Example 3, to manufacture a semiconductor device including separated polysilicon plugs which do not have step differences and defects.

### EXAMPLE 10

The procedure of Example 7 was repeated except for using the slurry of Example 4, instead of using the slurry of Example 1, to manufacture a semiconductor device including separated polysilicon plugs which do not have step differences and defects.

### EXAMPLE 11

A CMP process was performed on the resulting structure of FIG. 7d under a polishing pressure of 4 psi and a table revolution number of 80 rpm (Rotary Type CMP equipment) by using a hard pad and the slurry of Example 5, to manufacture a semiconductor device including an STI type device isolation film which does not have scratches.

### EXAMPLE 12

A CMP process was performed on the resulting structure of FIG. 7d under a polishing pressure of 4 psi and a table revolution number of 500 rpm (Orbital Type CMP equipment) by using a hard pad and the slurry of Example 6, to manufacture a semiconductor device including an STI type device isolation film which does not have scratches.

As discussed earlier, in accordance with the present invention, when the complex film consisting of the polysilicon film and the oxide film is removed via the CMP process using the slurry including the anion compound having high affinity to the nitride film, the hard mask film which is the nitride film is not removed. Thus, the polysilicon plug of the semiconductor device can be formed without exposing the word line electrode. As a result, misalignment errors are not generated in the subsequent process, a bridge is not formed between the word line wire and the storage node contact, and leakage current is not generated, to prevent failure of the device and improve a yield of the device.

In addition, the polishing process is performed with the high polishing selectivity to the oxide film by using the slurry including the anion compound having high affinity to the nitride film and spherical shaped particles, such as Al2O3 or SiO2, to form the STI type device isolation film which does not have scratches.

What is claimed is:

1. A CMP slurry composition for a complex film having a polysilicon film and an oxide film, or an oxide film, the CMP slurry composition comprising:
an anion compound;
an abrasive; and
water.

2. The composition according to claim 1, wherein the anion compound includes at least one compound selected from the group consisting of RCO2M, ROSO3M, RSO3M, RPO4M2 and R3N, wherein R is C10-C50 aliphatic hydrocarbon group, or C10-C50 aromatic hydrocarbon group; M is a hydrogen ion, an alkaline metal ion, an alkaline earth metal ion, or NH4+; and R of R3N is identical or different.

3. The composition according to claim 2, wherein the aliphatic and aromatic hydrocarbon groups comprise at least one of ethylene oxide group, carbon-carbon double bond and carbon-carbon triple bond, respectively.

4. The composition according to claim 3, wherein the anion compound is selected from the group consisting of lauric acid, oleic acid, stearic acid, sodium stearate, sodium lauric sulfate, sodium lauryl ether sulfate, ammonium lauryl sulfate, triethanol ammonium lauryl sulfate, sodium octyl sulfate, dodecyl benzene sulfonic acid, sodium dodecyl benzene sulfonate, mono lauryl phosphate, lauryl ether phosphate and dimethyl laurylamine.

5. The composition according to claim 1, wherein a size of the abrasive ranges from 20 to 300 nm.

6. The composition according to claim 1, wherein the anion compound is present in an amount ranging from 0.01 to 10 wt % of the total weight of slurry, and the abrasive is present in an amount ranging from 0.5 to 40 wt % of the total weight of slurry.

7. The composition according to claim 6, which is used to polish a complex film consisting of a polysilicon film and an oxide film.

8. The composition according to claim 6, wherein the anion compound is present in an amount ranging from 0.01 to 5 wt % of the total weight of slurry.

9. The composition according to claim 6, wherein the abrasive is selected from the group consisting of colloidal SiO2, fumed SiO2, Al2O3, CeO2 and combinations thereof.

10. The composition according to claim 6, wherein pH of the slurry ranges from 2 to 7.

11. The composition according to claim 6, wherein pH of the slurry ranges from 3 to 6.

12. The composition according to claim 1, wherein the anion compound is present in an amount ranging from 0.01 to 2 wt % of the total weight of slurry, and the abrasive is present in an amount ranging from 0.5 to 40 wt % of the total weight of slurry.

13. The composition according to claim 12, which is used to polish an oxide film.

14. The composition according to claim 12, wherein the anion compound is present in an amount ranging from 0.1 to 1.5 wt % of the total weight of slurry.

15. The composition according to claim 12, wherein the abrasive is selected from the group consisting of SiO2, Al2O3 and combinations thereof.

16. The composition according to claim 12, wherein pH of the slurry ranges from 2 to 9.

17. The composition according to claim 16, wherein pH of the slurry ranges from 3 to 7.

18. A method for forming a polysilicon plug of a semiconductor device, the method comprising:
(a) forming a stacked pattern of a word line and a hard mask film on a semiconductor substrate;
(b) forming a spacer on the sidewalls of the stacked pattern;
(c) forming an interlayer insulating film on the whole surface of the resulting structure;
(d) forming a polysilicon plug contact hole by defining a polysilicon plug contact hole region and selectively etching the interlayer insulating film to expose the stacked pattern present in the contact hole region;
(e) depositing a polysilicon film on the whole surface of the resulting structure; and
(f) performing a CMP process on the whole surface of the resulting structure by using the slurry of claim 1 until the hard mask film is exposed.

19. The method according to claim 18, wherein the word line is selected from the group consisting of a polysilicon film, a doped silicon film, WSix film, WN film, W film, TiSix film, and combinations thereof.

20. The method according to claim 18, wherein the word line pattern is formed via a plasma etching process using C12 or CC14 gas as a source.

21. The method according to claim 18, wherein the hard mask film is a nitride film.

22. The method according to claim 18, wherein the interlayer insulating film is selected from the group consisting of a BPSG(borophospho silicate glass) oxide film, PSG(phospho silicate glass) oxide film, FSG(fluoro silicate glass) oxide film, PE-TEOS(plasma enhanced-tetraethyl ortho silicate) oxide film, PE-SiH4 oxide film, HDP USG(high density plasma undoped silicon glass) oxide film, APL(advanced planarization layer) oxide film, and combinations thereof.

23. The method according to claim 18, wherein the polysilicon plug contact hole is formed according to a self-alignment contact process using C4F8 as a source.

24. The method according to claim 18, wherein the polysilicon film is formed according to in-situ doping process.

25. The method according to claim 18, wherein the step (f) is performed by using a hard pad under the conditions of a polishing pressure of 2 to 6 psi and a table revolution number of 10 to 700 rpm, or a table movement speed of 100 to 700 fpm.

26. The method according to claim 18, wherein a polishing selectivity of the hard mask film:polysilicon film: interlayer insulating film in step (f) is in the range of 1:2˜10:2˜10.

27. A method for forming an STI type device isolation film of a semiconductor device, comprising:
(a) sequentially forming a pad oxide film and a pad nitride film on a semiconductor substrate;
(b) forming a trench on a presumed device isolation region of the semiconductor substrate, by etching the pad nitride film, the pad oxide film and a predetermined thickness of semiconductor substrate via a photoetching process using a device isolation mask;
(c) forming a sidewall oxide film on the surface of the semiconductor substrate which has been exposed during the trench forming process and the sidewalls of the pad oxide film;
(d) forming a filling oxide film on the whole surface of the resulting structure;
(e) performing a CMP process on the filling oxide film by using the pad nitride film as a polishing barrier film and using the slurry of claim 1 until the pad nitride film is exposed; and
(f) removing the pad nitride film from the resulting structure.

28. The method according to claim 27, wherein the pad oxide film is formed at a thickness of 10 to 200 Å via a dry oxidation process using O2 source or a wet oxidation process using H2O source.

29. The method according to claim 27, wherein the pad nitride film is formed at a thickness of 200 to 2000 Å via a LPCVD(low pressure chemical vapor deposition) process using SiH2Cl2 and NH3 as a source, or a PECVD(plasma enhanced chemical vapor deposition) process using SiH4 and NH3 as a source.

30. The method according to claim 27, wherein a depth of the trench ranges from 1500 to 3000 Å.

31. The method according to claim 27, wherein the sidewall oxide film is formed at a thickness of 50 to 200 Å.

32. The method according to claim 27, wherein the filling oxide film is selected from the group consisting of an HDP(high density plasma) oxide film, PE-TEOS(plasma enhanced-tetraethyl ortho silicate) oxide film, O3-TEOS(O3-tetraethyl ortho silicate) oxide film, APL(advanced planarization layer) oxide film, BPSG(borophospho silicate glass) oxide film, PSG(phospho silicate glass) oxide film, and combinations thereof.

33. The method according to claim 27, wherein step (e) is performed by using a hard pad under the conditions of a polishing pressure of 2 to 6 psi and a table revolution number of 10 to 700 rpm, or a table movement speed of 100 to 700 fpm.

34. The method according to claim 27, wherein step (f) is performed by using H3PO4 as a main constituent.
